(19) United States
(12) Patent Application Publication
(10) Pub. No.: US 2025/0210589 A1
(43) Pub. Date: Jun. 26, 2025

(54) SEMICONDUCTOR PACKAGE AND MANUFACTURING METHOD THEREOF

(71) Applicant: Taiwan Semiconductor Manufacturing Company, Ltd., Hsinchu (TW)

(72) Inventors: Tzuan-Horng Liu, Taoyuan City (TW); An-Jhih Su, Taoyuan City (TW); Chung-Ming Weng, Taichung City (TW)

(73) Assignee: Taiwan Semiconductor Manufacturing Company, Ltd., Hsinchu (TW)

(21) Appl. No.: 18/393,711

(22) Filed: Dec. 22, 2023

(51) Int. Cl. H01L 25/065; H01L 21/768; H01L 23/00; H01L 23/48; H01L 23/58

(52) U.S. Cl. CPC H01L 25/0657; H01L 21/76898; H01L 23/481; H01L 23/585; H01L 24/14; H01L 24/16; H01L 24/32; H01L 2224/14515; H01L 2224/16145; H01L 2224/32145; H01L 2225/06562

(57) ABSTRACT

A semiconductor package and a manufacturing method thereof are provided. The semiconductor package includes: a first device die and a second device die stacked over the first device die; functional bumps, disposed between the first device die and the second device die, and electrically connected to the first device die and the second device die; and a first seal ring, comprising at least one dummy bump arranged along edges of the first device die and disposed between the first and second device dies, and laterally surrounding the functional bumps.

### BACKGROUND

Semiconductor industry has strived to continually reduce feature size and power consumption of various electronic components, while on the other hand increasing device density, wire density and operation frequency of the electronic components. These advanced electronic components also require smaller packages that utilize less area than packages of the past.

Three-dimensional integrated circuit (3DIC) is a recent development in semiconductor packaging in which multiple dies are stacked upon one another. 3DIC provides improved integration density and other advantages, such as greater operation speed and higher bandwidth, because of the decreased length of interconnects between the stacked dies. However, there are quite a few challenges to be overcome for the technology of 3DICs. For instance, connectors configured to connect vertically separated dies in a 3DIC may be subjected to damages caused by stress or invasion of moisture and/or chemicals, and suffer from low reliability.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic cross-sectional view illustrating a semiconductor package, according to some embodiments of the present disclosure.

FIG. 1B is a schematic plan view of the semiconductor package shown in FIG. 1A, according to some embodiments of the present disclosure.

FIG. 1C is an enlarged schematic cross-sectional view showing a dummy through substrate via and surrounding features in the semiconductor package shown in FIG. 1A, according to some embodiments of the present disclosure.

FIG. 2A through FIG. 2C are schematic cross-sectional views illustrating a process for bonding a bottom device die with a middle redistribution structure in the semiconductor package shown in FIG. 1A, according to some embodiments of the present disclosure.

FIG. 3A through FIG. 3H are schematic cross-sectional views illustrating an overall process for forming the semiconductor package shown in FIG. 1A, according to some embodiments of the present disclosure.

FIG. 4 is a schematic cross-sectional view illustrating a semiconductor package, according to some embodiments of the present disclosure.

FIG. 5A through FIG. 5E are schematic plan views illustrating semiconductor packages, according to some embodiments of the present disclosure.

FIG. 6A is an enlarged schematic cross-sectional view partially showing a package seal ring in the semiconductor package shown in FIG. 5D, according to some embodiments of the present disclosure.

FIG. 6B is an enlarged schematic cross-sectional view partially showing a package seal ring in the semiconductor package shown in FIG. 5D, according to some other embodiments of the present disclosure.

FIG. 6C is an enlarged schematic cross-sectional view partially showing a package seal ring in the semiconductor package shown in FIG. 5E, according to some other embodiments of the present disclosure.

FIG. 7A is a schematic cross-sectional view illustrating a semiconductor package, according to some embodiments of the present disclosure.

FIG. 7B is a schematic plan view of the semiconductor package shown in FIG. 7A, according to some embodiments of the present disclosure.

FIG. 8 is a schematic cross-sectional view illustrating a semiconductor package, according to some embodiments of the present disclosure.

FIG. 9A through FIG. 9E are schematic cross-sectional views illustrating a process for forming the semiconductor package shown in FIG. 8, according to some embodiments of the present disclosure.

### DETAILED DESCRIPTION

The following disclosure provides many different embodiments or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides a solution for enhancing reliability of connectors establishing connection between vertically separated dies in a three-dimensional semiconductor package (or referred to as a 3DIC).

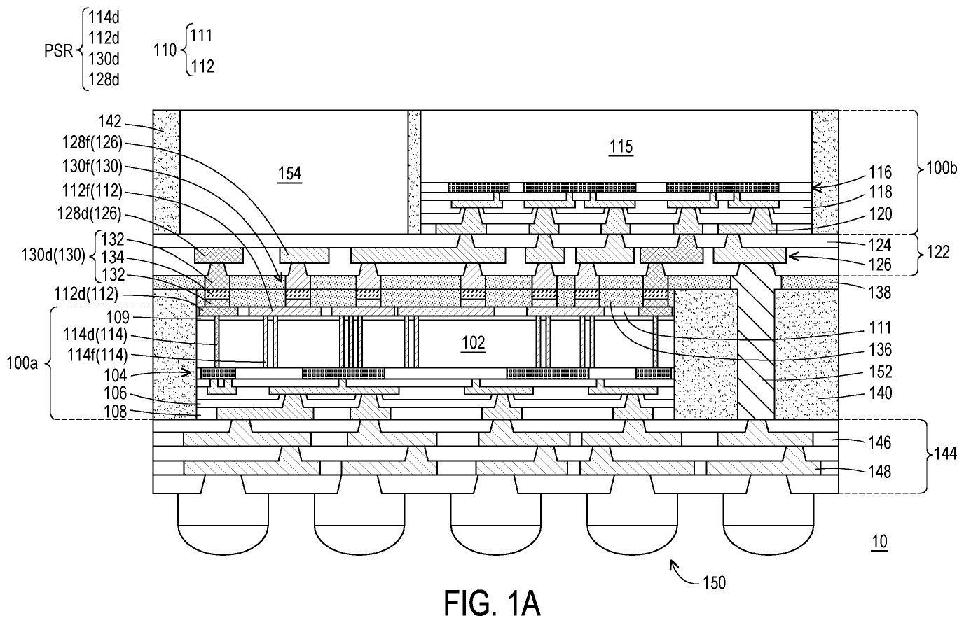

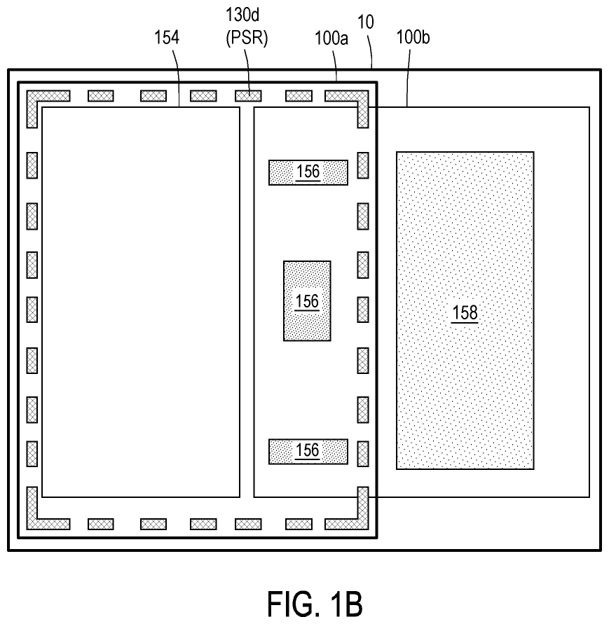

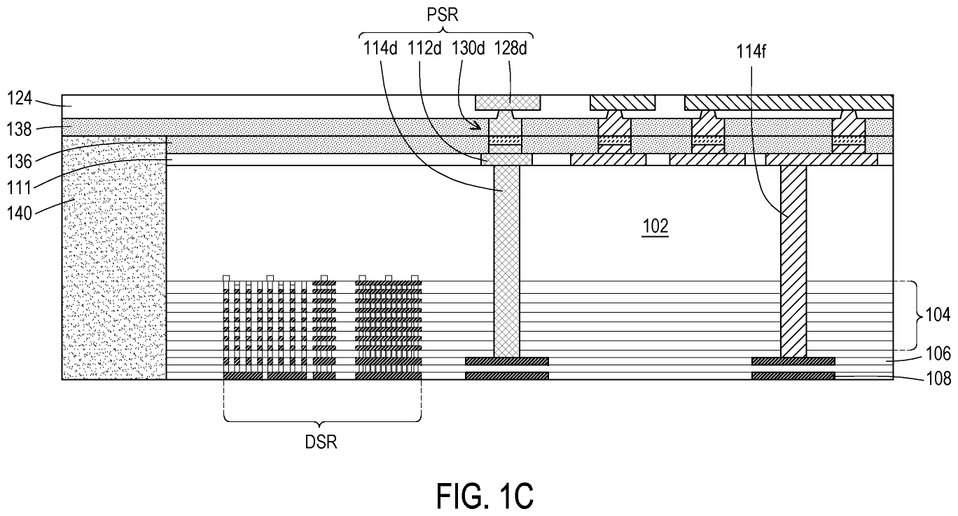

FIG. 1A is a schematic cross-sectional view illustrating a semiconductor package 10, according to some embodiments of the present disclosure.

The semiconductor package 10 is a three-dimensional semiconductor package, as a device die 100a and a device die 100b in the semiconductor package 10 are arranged in a stacking manner. Specifically, the device die 100b is stacked over the device die 100a, and the device dies 100a, 100b are communicated with each other through vertical and lateral conduction paths established in between. In terms of functionality, dimension and/or technology node, the device die 100a may be the same as or different from the device die 100b.

The device die 100a includes a semiconductor substrate 102 with a front side and a back side facing away from the front side. Active devices (not shown) may be deployed at the front side of the semiconductor substrate 102, and metallization layers 104 (only a single one is shown) including conductive features for interconnecting the active devices are stacked over the active devices. Further dielectric layers 106 may be formed over the metallization layers 104, and routing elements 108 embedded in the dielectric layers 106 connect the conductive features in the metallization layers 104 to a front side of the device die 100a.

According to a face-to-back die stacking configuration, while the active side of the device die 100a faces away from the overlying device die 100b, a back side of the device die 100a faces toward the device die 100b. In some embodiments, the back side of the device die 100a is defined by a back side redistribution structure 110 formed on a liner layer 109 covering the back side of the semiconductor substrate 102. The back side redistribution structure 110 may include at least one dielectric layer 111 and conductive patterns (e.g., conductive pads 112) spreading in the dielectric layer 111. To establish connection from the front side to the back side of the semiconductor substrate 102, through substrate vias 114 are formed through the semiconductor substrate 102. In those embodiments where the liner layer 109 and the conductive pads 112 are disposed on the back side of the semiconductor substrate 102, the through substrate vias 114 extend through the liner layer 109, to reach the conductive pads 112. As some of the through substrate vias 112 participate in signal transmission, these through substrate vias 114 are also referred to as functional through substrate vias 114f. In those embodiments where the through substrate vias 114 extend to the conductive pads 112, the conductive pads 112 in contact with the functional through substrate vias 114f are referred to as functional conductive pads 112f. In addition to the functional through substrate vias 114f, the through substrate vias 114 may also include dummy through substrate vias 114d, which may not participate in signal transmission, but are electrically floated or grounded. To shield the functional through substrate vias 114f from possible damages during die singulation, the dummy through substrate vias 114d are separately arranged along edges of the device die 100a, and laterally surround the functional through substrate vias 114f. In those embodiments where the through substrate vias 114 extend to the conductive pads 112, the conductive pads 112 in contact with the dummy through substrate vias 114d are referred to as dummy conductive pads 112d. Since the functional through substrate vias 114f are surrounded by the dummy through substrate vias 114d, the functional conductive pads 112f covering the functional through substrate vias 114f are laterally surrounded by the dummy conductive pads 112d covering the dummy through substrate vias 114d.

As similar to the device die 100a, the device die 100b includes a semiconductor substrate 115 with a front side and a back side facing away from the front side. Active devices (not shown) may be formed at the front side of the semiconductor substrate 115, and metallization layers 116 (only a single one is shown) including conductive features for interconnecting the active devices are stacked over the active devices. Also, dielectric layers 118 may be formed over the metallization layers 116, and routing elements 120 embedded in the dielectric layers 118 connect the conductive features in the metallization layers 116 to a front side of the device die 100b. According to the face-to-back die stacking configuration, the front side of the device die 100b faces toward the back side of the device die 100a. On the other hand, a back side of the device die 100b faces away from the device die 100a. As a difference from the device die 100a, the device die 100b may not include through substrate vias, and the back side of the device die 100b may be defined by the back side of the semiconductor substrate 115.

A redistribution structure 122 is inserted in between the device dies 100a, 100b, for redistributing terminals of the device die 100b and establishing connection between the device dies 100a, 100b. Specifically, the redistribution structure 122 includes a stack of dielectric layers 124 and redistribution elements 126 spreading in the stack of dielectric layers 124. According to some embodiments, the dielectric layers 124 are implemented by polymer layers. In addition, the redistribution elements 126 include a combination of conductive patterns and conductive vias. Some of the redistribution elements 126 connect the terminals of the device die 100b (e.g., provided by some routing elements 120) to positions in line with terminals of the device die 100a (e.g., provided by the conductive pads 112). Specifically, functional conductive pads 128f of the redistribution elements 126 overlap the functional conductive pads 112f of the device die 100a, whereas dummy conductive pads 128d of the redistribution elements 126 overlap the dummy conductive pads 112d of the device die 100a. As described, the dummy conductive pads 112d are arranged around the functional conductive pads 112f, thus the dummy conductive pads 128f overlying the dummy conductive pads 112d may be arranged around the functional conductive pads 128f overlying the functional conductive pads 112f.

Bumps 130 are used for electrically connecting the functional and dummy conductive pads 128f, 128d in the redistribution structure 122 to the functional and dummy conductive pads 112f, 112d of the device die 100a. Specifically, functional bumps 130f establish electrical connection between the functional conductive pads 128f, 112f, and dummy bumps 130d establish electrical connection between the dummy conductive pads 128d, 112d. As the functional conductive pads 112f are laterally surrounded by the dummy conductive pads 112d, the functional bumps 130f standing on the functional conductive pads 112f are laterally surrounded by the dummy bumps 130d standing on the dummy conductive pads 112d.

The dummy through substrate vias 114d and the dummy conductive pads 112d of the device die 100a, the dummy conductive pads 128d in the redistribution structure 122 and the dummy bumps 130d in between the device die 100a and the redistribution structure 122 are connected to form a package seal ring PSR. The functional through substrate vias 114f and the functional conductive pads 112f of the device die 100a, the functional conductive pads 128f in the redistribution structure 122 and especially the functional bumps 130f in between the device die 100a and the redistribution structure 122 are laterally surrounded by the package seal ring PSR, and can be protected by the package seal ring PSR from damages caused by stress resulted during singulation of the semiconductor package 10 and/or moisture/chemicals laterally entering the semiconductor package 10. Therefore, as a similar effect to the functional through substrate vias 114f and the functional conductive pads 112f, 128f, reliability of the functional bumps 130f can be effectively improved.

In some embodiments, the bumps 130 are implemented by micro-bumps. As an example, each bump 130 may include a pair of conductive posts 132 and a solder layer 134 in between the conductive posts 132. The conductive posts 132 in each functional bump 130f may be in contact with one of the functional conductive pads 128f and one of the functional conductive pads 112f, respectively. On the other hand, the conductive posts 132 in each dummy bump 130d may be in contact with one of the dummy conductive pads 128d and one of the dummy conductive pads 112d, respectively.

Further, according to some embodiments, the bumps 130 are confined in openings of bonding layers 136, 138. The bonding layer 136 extends along the back side of the semiconductor substrate 102 in the device die 100a, and may cover back side redistribution structure 110. On the other hand, the bonding layer 138 extends along a bottommost dielectric layer 124 of the redistribution structure 122, and is bonded with the bonding layer 136. The conductive posts 132 in each bump 130 are laterally enclosed by the bonding layers 136, 138, respectively. In addition, the solder layer 134 in each bump 130 may be embedded in one of the bonding layers 136, 138 (e.g., embedded in the bonding layer 136 as shown in FIG. 1A). According to some embodiments, the bonding layers 136, 138 are each implemented by a polymer layer.

In some embodiments, the bonding layer 136 is singulated along with the device die 100a, thus sidewalls of the bonding layer 136 may be substantially coplanar with sidewalls of the device die 100a (which may be defined by sidewalls of the back side redistribution structure 110, the liner layer 109, the semiconductor substrate 102, the metallization layers 104 and the dielectric layers 106). Further, the singulated device die 100a and the bonding layer 136 may be laterally encapsulated by an encapsulant 140. While the device die 100a and the bonding layer 136 are embedded in the encapsulant 140, the bonding layer 138 as well as the redistribution structure 122 on top of the bonding layer 138 extend over the encapsulant 140. Therefore, in addition to being in lateral contact with the device die 100a and the bonding layer 136, the encapsulant 140 may be in contact with the bonding layer 138 from below.

As similar to the device die 100a, the device die 100b is encapsulated as well. An encapsulant 142 laterally encapsulating the device die 100b may be located on the redistribution structure 122, and vertically separated from the encapsulant 140 encapsulating the device die 100a and the bonding layer 136 via the redistribution structure 122 and the bonding layer 138. That is, the device dies 100a, 100b may be encapsulated by respective encapsulants (e.g., the encapsulants 140, 142), which are vertically spaced apart from each other.

While the device die 100a and the overlying device die 100b are communicated through the redistribution structure 122 in between, another redistribution structure 144 may be disposed below the device die 100a and the encapsulant 140, for routing the device dies 100a, 100b to the other side of the redistribution structure 144. As similar to the redistribution structure 122, the redistribution structure 144 may include a stack of dielectric layers 146 and redistribution elements 148 spreading in the stack of dielectric layers 146. According to the face-to-back die stacking configuration, the stack of dielectric layers 146 may be disposed along the front side of the device die 100a and a bottom side of the encapsulant 140, and the redistribution elements 148 may establish contact with front-side terminals of the device die 100a, which may be provided by the routing elements 108. In some embodiments, the front-side terminals may be routed by the redistribution elements 148 to package inputs/outputs (I/Os) 150 disposed along a bottom side of the redistribution structure 144. As an example, the package I/Os 150 may be implemented by C4 bumps.

According to some embodiments, the semiconductor package 10 is singulated by cutting through the encapsulants 140, 142, the redistribution structures 122, 144 and the bonding layer 138. In these embodiments, sidewalls of the encapsulants 140, 142, the redistribution structures 122, 144 and the bonding layer 138 are substantially coplanar.

Further, in some embodiments, the device die 100b is laterally offset with respect to the device die 100a. In these embodiments, a first portion of the device die 100b overlaps the device die 100a, whereas a second portion of the device die 100b lies outside the range of the device die 100a. In this way, the second portion of the device die 100b can be in contact with the redistribution structure 144 through the redistribution structure 122, the bonding layer 138 and the encapsulant 140, without the device die 100a in between. In addition, through encapsulant vias 152 (only a single one is shown) may be disposed to establish connection between the second portion of the device die 100b and the redistribution structure 144. Specifically, the through encapsulant vias 152 aside the device die 100a may penetrate through the encapsulant 140 and the bonding layer 138, and bounded to the redistribution structures 122, 144 by opposite ends. The terminals of the device die 100b within the second portion of the device die 100b may be connected to the redistribution elements 148 in the redistribution structure 144 through the redistribution elements 126 in the redistribution structure 122 and the through encapsulant vias 152, and may be further routed to the package I/Os 150 via the redistribution elements 148 in the redistribution structure 144.

Moreover, in those embodiments where the device die 100b is laterally offset with respect to the device die 100a, a dummy die 154 (or more) may be further embedded in the encapsulant 142, to balance non-uniformity of thermal expansion coefficient across the encapsulant 142. For instance, when the device die 100b is deviated to the right side of a location directly above the device die 100a, a dummy die 154 may be disposed at a left side of the deviated device die 100b. The dummy die 154 may not be formed with circuits. As an example, the dummy die 154 may be implemented by a chip of a semiconductor material with a thickness substantially identical with a thickness of the encapsulant 142.

FIG. 1B is a schematic plan view of the semiconductor package 10, according to some embodiments of the present disclosure. It should be noted that, for illustration purpose, only a few elements in the semiconductor package 10 are shown in FIG. 1B.

Referring to FIG. 1B, the device dies 100a, 100b and the dummy die 154 are located within a boundary of the semiconductor package 10, which may be defined by the sidewalls of the encapsulants 140, 142, the redistribution structures 122, 144 and the bonding layer 138. In addition, the dummy bumps 130d of the package seal ring PSR are separately arranged along edges of the device die 100a.

According to some embodiments, some of the dummy bumps 130d each extending along a single edge of the device die 100a are formed as wall structures, which are shown as line segments in the plan view of FIG. 1B. Further, others of the dummy bumps 130d may respectively extend along intersected edges of the device die 100a, and are each shown as a pattern with “L” shape in the plan view of FIG. 1B. Although not shown, the dummy conductive pads 112d, 128d of the package seal ring PSR at bottom and top sides of the dummy bumps 130d are similar in top view shape with the dummy bumps 130d in between. For instance, the dummy conductive pads 112d, 128d at bottom and top sides of the dummy bumps 130d with segmental top views may be formed as line segments as well. As another example, the dummy conductive pads 112d, 128d at bottom and top sides of the dummy bumps 130d with “L” shape top views may be formed in “L” shape as well. On the other hand, the dummy through substrate vias 114d of the package seal ring PSR may not be formed with top views in accordance with top views of the dummy bumps 130d. For instance, while the dummy bumps 130d are formed with top views in line shape and “L shape”, the dummy through substrate vias 114d may be formed as pillar structures with circular top views. Also, as compared to the dummy bumps 130d in segmental or “L” shape top views, the functional bumps 130f may be respectively formed as a pillar structure having a circular top views.

As further shown in FIG. 1B, die-to-die connection may be at least implemented in regions 156 overlapped with both of the device dies 100a, 100b. As described, the device dies 100a, 100b may be connected with each other through the functional conductive pads 128f, 112f, the functional bumps 130f and the functional through substrate vias 114f, and these interconnecting elements may be at least partially located in the regions 156.

As also shown in FIG. 1B, connection between the device die 100b and the redistribution structure 144 may be established within a region 158 overlapped with the second portion of the device die 100b located outside the range of the device die 100a. As described, the connection between the device die 100b and the redistribution structure 144 may be established through the redistribution structure 122 and the through encapsulant vias 152.

FIG. 1C is an enlarged schematic cross-sectional view showing one of the dummy through substrate vias 114d and surrounding features, according to some embodiments of the present disclosure.

Referring to FIG. 1C, as similar to the functional through substrate vias 114f, the dummy through substrate vias 114d may extend through the semiconductor substrate 102 of the device die 100a. According to some embodiments, the dummy through substrate vias 114d and the functional through substrate vias 114f may further extend through dielectric layers of the metallization layers 104, and land on some of the routing elements 108 spreading in the dielectric layers 106. As described, the dummy through substrate vias 114d may be arranged in a peripheral region of the device die 100a, such that the functional through substrate vias 114f may be laterally surrounded by the dummy through substrate vias 114d. Nevertheless, the dummy through substrate vias 114d may still be laterally spaced apart from the edges of the device die 100a. According to some embodiments, a die seal ring DSR may be disposed in between the dummy through substrate vias 114d and the edges of the device die 100a. Specifically, the die seal ring DSR laterally surrounding the dummy through substrate vias 114d may be formed through the dielectric layers of the metallization layers 104 and the dielectric layers 106 formed on the metallization layers 104, and may include alternate layers of conductive patterns and conductive vias.

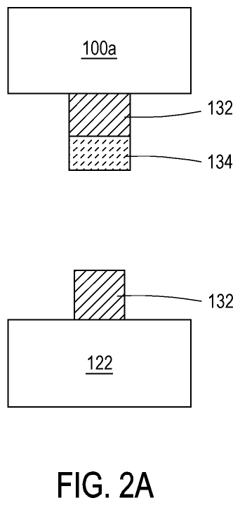

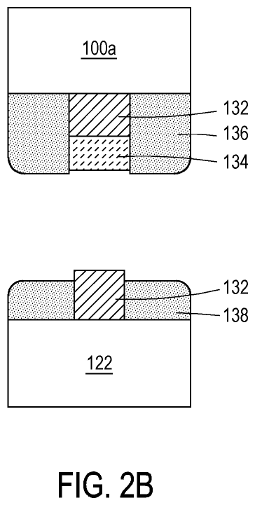

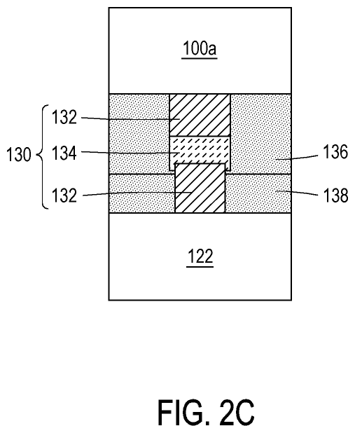

FIG. 2A through FIG. 2C are schematic cross-sectional views illustrating a process for bonding the device die 100a with the redistribution structure 122, according to some embodiments of the present disclosure.

Referring to FIG. 2A, the process may begin with forming the conductive posts 132 and the solder layer 134 on the device die 100a and the redistribution structure 122. Specifically, a half of the conductive posts 132 may be formed on the device die 100a, and the other half of the conductive posts 132 may be formed on the redistribution structure 122. In addition, the solder layers 134 may be formed on the conductive posts 132 standing on the device die 100a, or formed on the conductive posts 132 standing on the redistribution structure 122. For illustration purpose, the process will be described according to the example that the solder layers 134 are formed on the conductive posts 132 standing on the device die 100a.

Specifically, a seed layer (or more) is initially deposited on each of the device die 100a and the redistribution structure 122. Subsequently, a mask layer (e.g., a photoresist layer) may be formed over each of the device die 100a and the redistribution structure 122, and may be patterned with opening exposing the underlying seed layer. Thereafter, one or a series of plating processes may be performed to deposit one or a stack of metallic layers in each opening. In addition, an additional plating process may be performed to provide a solder material on the metallic layers over the device die 100a. Afterwards, the mask layer may be removed, and portions of the seed layers not shielded by the metallic layers are removed as well. The metallic layers and the remained portions of the seed layers form the conductive posts 132, while the solder material form the solder layers 134.

Referring to FIG. 2B, the bonding layers 136, 138 are formed on the device die 100a and the redistribution structures 122, respectively. According to some embodiments, the bonding layer 136 covering the device die 100a may be formed to a thickness greater than a total thickness of the solder layers 134 and the conductive posts 132 on the device die 100a, whereas the bonding layer 138 covering the redistribution structure 122 may be formed to a thickness less than a thickness of the conductive posts 132 standing on the redistribution structure 122. In these embodiments, the conductive posts 132 and the solder layers 134 on the device die 100a may be recessed with respect to the bonding layer 136, whereas the conductive posts 132 on the redistribution structure 122 may be protruded with respect to the bonding layer 138.

Referring to FIG. 2C, a bonding operation is performed that the bonding layers 136, 138 are bonded with each other, and the conductive posts 132 formed on the device die 100a are jointed with the conductive posts 132 formed on the redistribution structure 122 through the solder layers 134. In this way, the bumps 130 each including upper and lower conductive posts 132 and a solder layer 134 in between are formed with lateral confinement provided by the bonding layers 136, 138. As being confined by the bonding layers 136, 138, the bumps 130 can be arranged with fine pitch while shorting resulted from expansion during the bonding can be effectively prevented. According to some embodiments, the bonding operation includes at least one heating treatment.

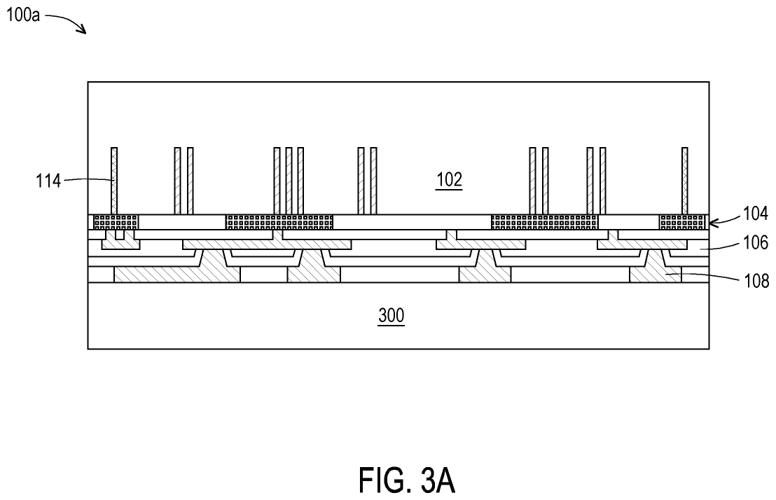

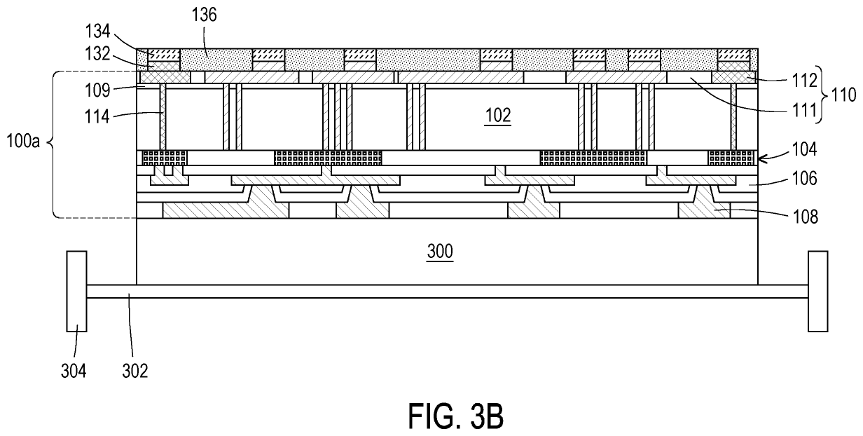

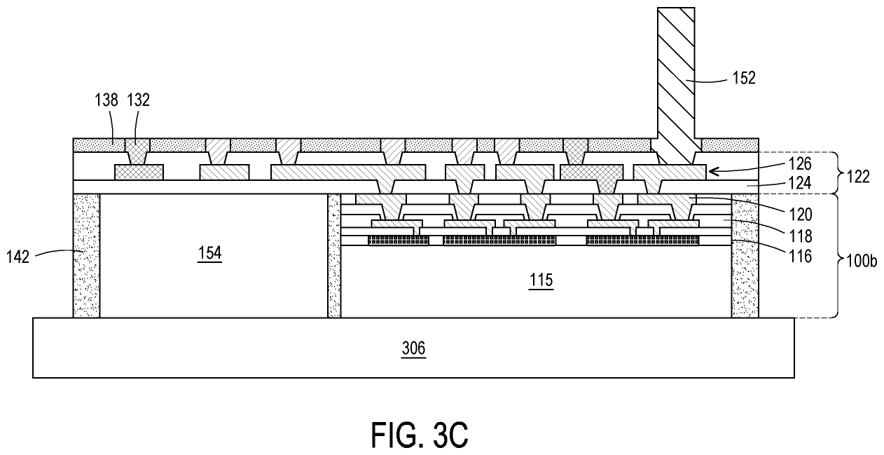

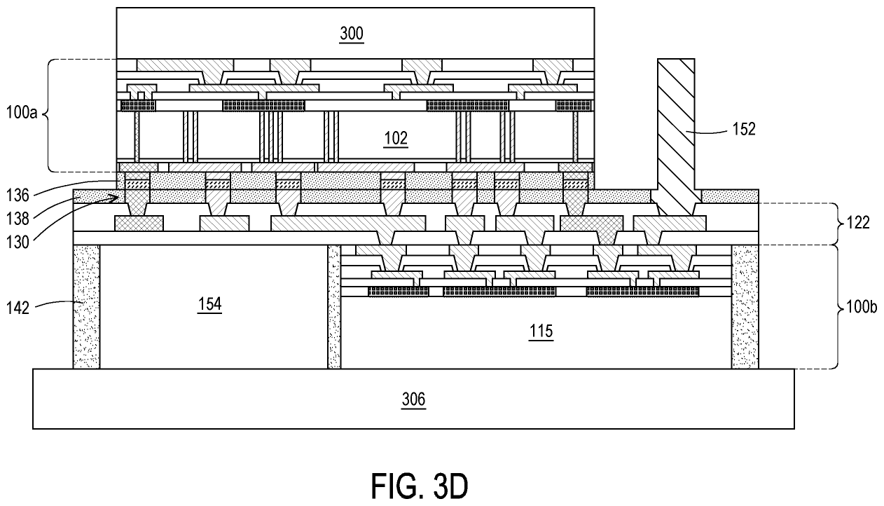

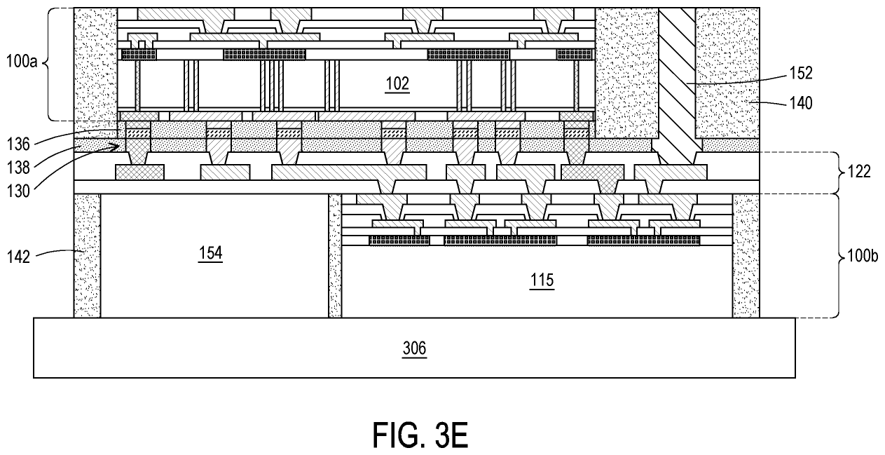

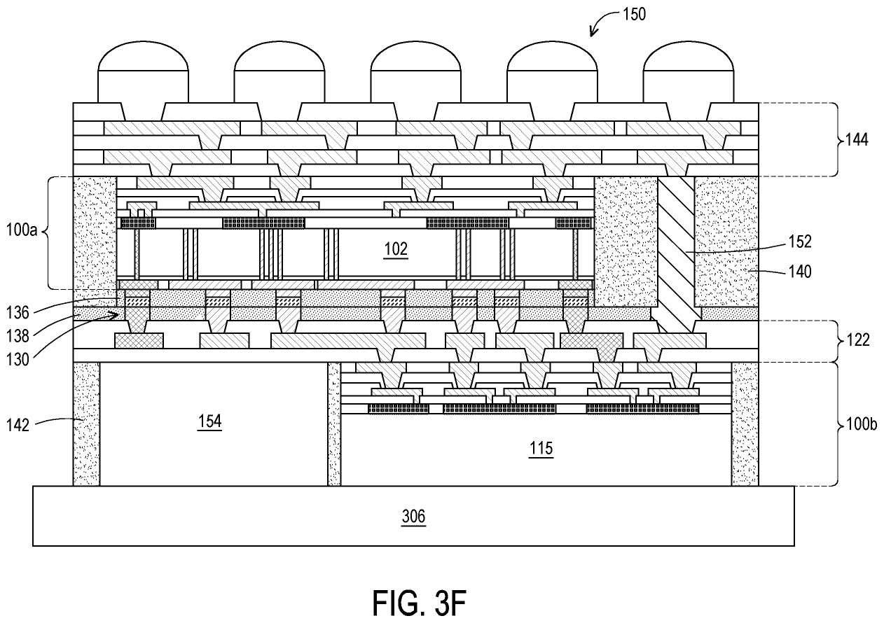

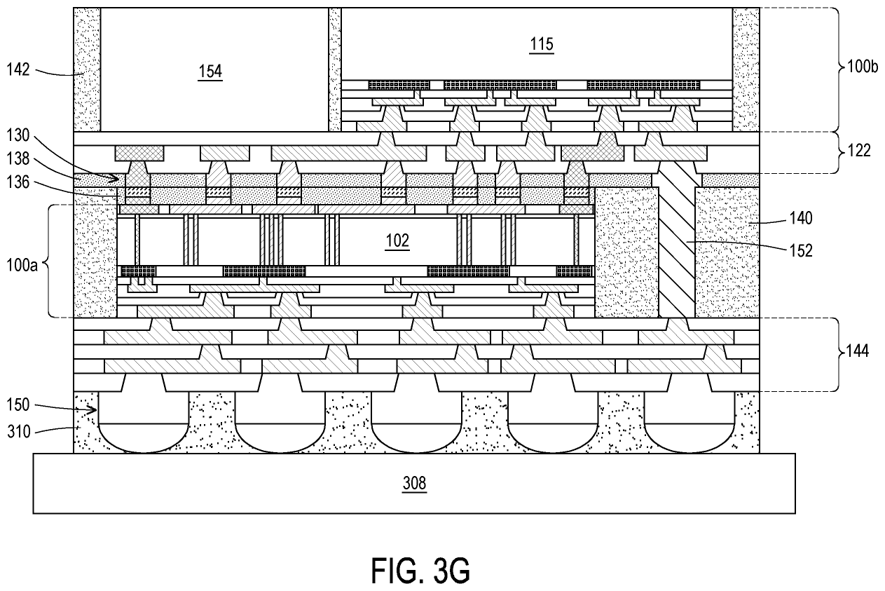

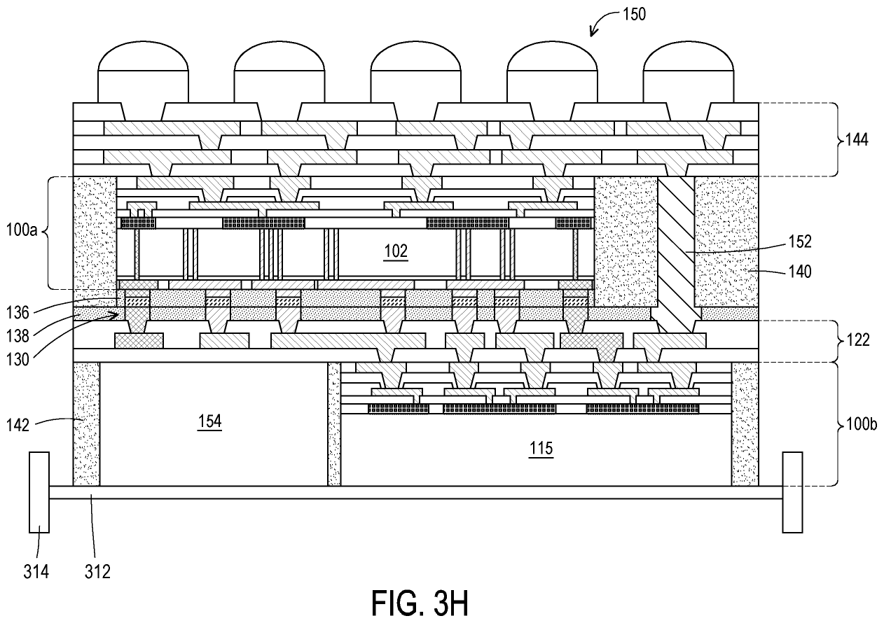

FIG. 3A through FIG. 3H are schematic cross-sectional views illustrating an overall process for forming the semiconductor package 10, according to some embodiments of the present disclosure.

Referring to FIG. 3A, after front side processing, the device die 100a in wafer form is bonded onto a supporting substrate 300 by front side. Currently, the semiconductor substrate 102 of the device die 100a has not been thinned from back side, or has not been thinned to an eventual thickness. Thereby, the through substrate vias 114 are not exposed at the back side of the semiconductor substrate 102, but are embedded in the semiconductor substrate 102. Further, the liner layer 109 and the back side redistribution structure 110 have not been formed.

Referring to FIG. 3B, the semiconductor substrate 102 is then thinned from back side, to expose the through substrate vias 114. In addition, the device die 100a is subjected to back side processing, such that the liner layer 109 and the back side redistribution structure 110 are formed along the back side of the semiconductor substrate 100. Also, the bonding layer 136 as well as a half of the conductive posts 132 and the solder layers 134 are formed over the device die 100a in a process described with reference to FIG. 2A and FIG. 2B. Moreover, the device die 100a and the bonding layer 136 formed thereon are singulated while the supporting substrate 300 is attached to a tape 302 held by a frame 304.

Referring to FIG. 3C, while the device die 100a and bonding features formed thereon (i.e., the bonding layer 136 as well as the conductive posts 132, the solder layers 134 surrounded by the bonding layer 136) are prepared, the device die 100b and the dummy die 154 (both in chip form) supported by a carrier substrate 306 are encapsulated by the encapsulant 142. Also, the redistribution structure 122 is formed along the front side of the device die 100b as well as top sides of the encapsulant 142 and the dummy die 154. In addition, the other half of the conductive posts 132 and the bonding layer 138 are formed on the redistribution structure 122 in a process described with reference to FIG. 2A and FIG. 2B. Further, the through encapsulant vias 152 may be formed through the bonding layer 138, to establish contact with the redistribution structure 122.

Subsequently, in a process described with reference to FIG. 2C, the structure on the tape 302 as shown in FIG. 3B is flipped over and attached onto the structure shown in FIG. 3C. As a result shown in FIG. 3D, the bonding layers 136, 138 are bonded with each other, and the bumps 130 are assembled while being enclosed by the bonding layers 136, 138.

Referring to FIG. 3E, in a following stage, the supporting substrate 300 is removed from the device die 100a, then the encapsulant 140 is formed on the bonding layer 138 to laterally encapsulate the device die 100a and the through encapsulant vias 152. Alternatively, the encapsulant 140 may be formed at first, and a grinding process may be performed to remove the supporting substrate 300 and to planarize the encapsulant 140.

Referring to FIG. 3F, the redistribution structure 144 is then formed on the exposed front side of the device die 100a as well as the top side of the encapsulant 140. Thereafter, the package I/Os 150 may be disposed on the redistribution structure 144.

Referring to FIG. 3G, the carrier substrate 306 is removed, and a grinding process may be performed to thin the exposed device die 100b, dummy die 154 and encapsulant 142. According to some embodiments, while the carrier substrate 306 is detached from the encapsulant 142, the device die 100b and the dummy die 154, the package I/Os 150 are attached to another carrier substrate 308. An adhesive material 310 may be provided in between the redistribution structure 144 and the carrier substrate 308, to enhance adhesion of the current package structure to the carrier substrate 308.

Referring to FIG. 3H, as thinning operation is over, the resulted package structure may be flipped over and attached to a tape 312 (held by a frame 314) via the device die 100b, the dummy die 154 and the encapsulant 142, and the carrier substrate 308 and the adhesive material 310 may be removed. Further, the current package structure is subjected to singulation, to form the semiconductor package 10 as described with reference to FIG. 1A through FIG. 1C.

It should be appreciated that the semiconductor package 10 and manufacturing method thereof are only provided as examples. Many variations can be applied to the semiconductor package 10 and associated manufacturing process, and similar semiconductor packages and corresponding manufacturing processes can be resulted.

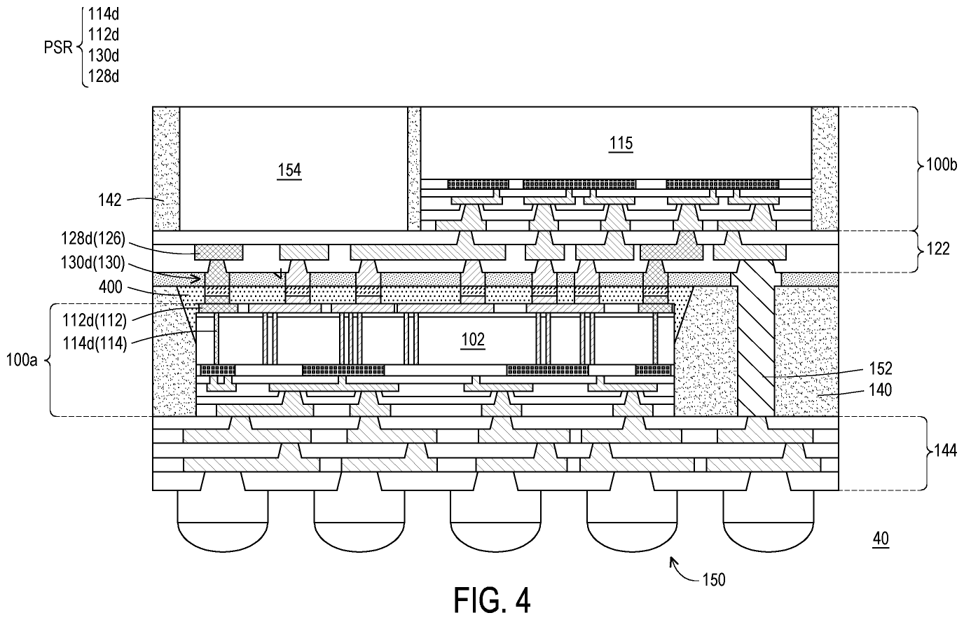

FIG. 4 is a schematic cross-sectional view illustrating a semiconductor package 40, according to some embodiments of the present disclosure.

The semiconductor package 40 is similar to the semiconductor package 10 described with reference to FIG. 1A through FIG. 1C, except that the bumps 130 are sealed by an underfill 400 provided between the device die 100a and the redistribution structure 122, rather than the bonding layers 136, 138. In regarding manufacturing, the bumps 130 are assembled (i.e., the lower conductive posts 132 are jointed with the upper conductive posts 132 through the solder layers 134) without the underfill 400 formed around. The underfill 400 is provided after assembly of the bumps 130.

A process described with reference to FIG. 2A through FIG. 2C and FIG. 3A through FIG. 3H can be used for forming the semiconductor package 40, but several modifications are required. Specifically, the bonding layers 136, 138 should be absent at the stages shown in FIG. 2B, FIG. 2C, FIG. 3B, FIG. 3C and FIG. 3D. After the upper and lower conductive posts 132 are jointed by the solder layers 134 to form the bumps 130 at the stage shown in FIG. 2C and FIG. 3D, the underfill 400 may be provided in between the redistribution structure 122 and the device die 100a to laterally encapsulate the bumps 130. As shown in FIG. 4, the underfill 400 may not entirely cover the redistribution structure 122. Accordingly, the subsequently formed encapsulant 140 may be in contact with the redistribution structure 122, and laterally surround the underfill 400.

Rest part of the process for forming the semiconductor package 40 may be similar to or even identical with the process described with reference to FIG. 2A through FIG. 2C and FIG. 3A through FIG. 3H, thus are not repeated again.

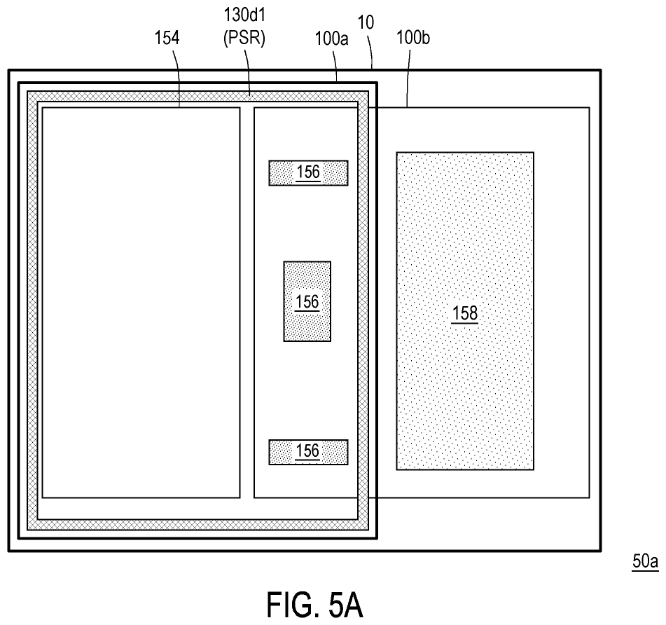

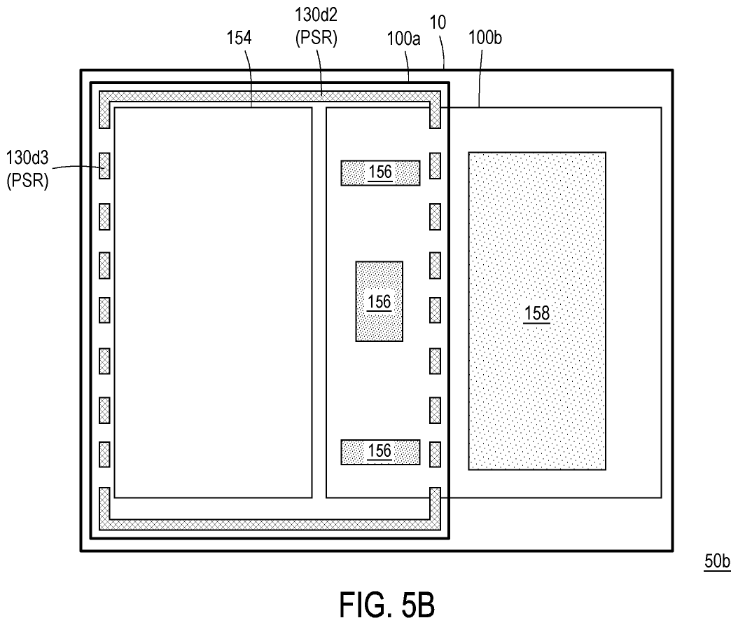

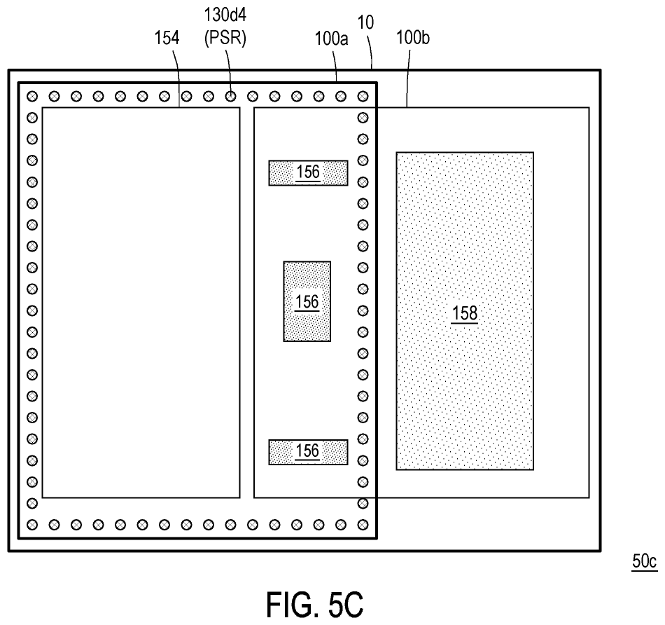

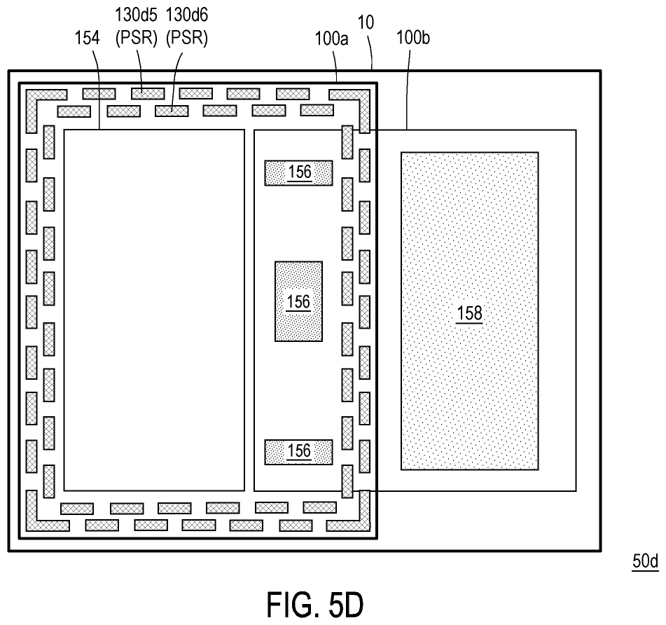

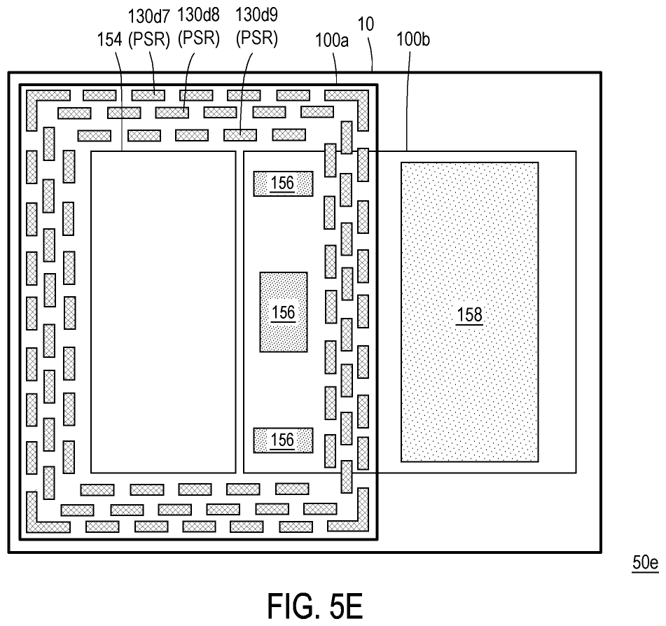

FIG. 5A through FIG. 5E are schematic plan views illustrating semiconductor packages 50a-50e, according to some embodiments of the present disclosure. Each of the semiconductor packages 50a-50e is substantially identical with the semiconductor package 10 described with reference to FIG. 1A through FIG. 1C or the semiconductor package 40 described with reference to FIG. 4, except for pattern design of the package seal ring PSR. It should be noted that, for illustration purpose, only a few elements in each of the semiconductor packages 50a-50e are shown. Detailed structure of rest part in each of the semiconductor packages 50a-50e can be referred to description with reference to FIG. 1A through FIG. 1C.

As a difference from the semiconductor package 10 described with reference to FIG. 1A through FIG. 1C, the package seal ring PSR in the semiconductor package 50a shown in FIG. 5A includes a single dummy bump 130d1 formed as an annulus wall and continuously extending along edges of the device die 100a. In this way, the functional bumps 130f are laterally enclosed by the annulus dummy bump 130d1, and can be more sufficiently protected by the annulus dummy bump 130dl. Although not shown, the dummy conductive pads 112d, 128d of the package seal ring PSR at bottom and top sides of the annulus dummy bump 130d1 are similar in top view shape with the annulus dummy bump 130d1 in between. That is, the annulus dummy bump 130d1 may be in contact with an annulus dummy conductive pad 112d from above, and in contact with an annulus dummy conductive pad 128d from below. On the other hand, the dummy through substrate vias 114d of the package seal ring PSR may not be formed in accordance with the annulus dummy bump 130dl. For instance, while lying below the annulus dummy bump 130d1, the dummy through substrate vias 114d may be formed as pillar structures with circular top views, and are separately arranged along the annulus dummy bump 130dl. Also, as compared to the annulus dummy bump 130d1, the functional bumps 130f are formed as pillar structures and may have circular top view shapes.

Referring to FIG. 5B, instead of having a single annulus dummy bump 130d1, the package seal ring PSR in the semiconductor package 50b may include linear dummy bumps 130d2 and segmental dummy bumps 130d3. The linear dummy bumps 130d2 may be respectively formed as a wall structure that appears to be a linear pattern in the top view, and may continuously extend along first and second edges of the device die 100a. On the other hand, the segmental dummy bumps 130d3 are structurally identical with the segmental dummy bumps 130d described with reference to FIG. 1A and FIG. 1B, and may be separately arranged along third and fourth edges of the device die 100a.

Although not shown, the dummy conductive pads 112d, 128d of the package seal ring PSR at bottom and top sides of the dummy bumps 130d2, 130d3 may be formed in accordance with the dummy bumps 130d2, 130d3. Specifically, the linear dummy bumps 130d2 may be respectively in contact with a linear dummy conductive pad 112d from above, and in contact with a linear dummy conductive pad 128d from below. In addition, the segmental dummy bumps 130d3 may be disposed between and in connection with segmental dummy conductive pads 112d and segmental dummy conductive pads 128d. On the other hand, the dummy through substrate vias 114d of the package seal ring PSR may not be formed in accordance with the dummy bumps 130d2, 130d3. For instance, while lying below the linear dummy bumps 130d2 and the segmental dummy bumps 130d3, the dummy through substrate vias 114d may be formed as pillar structures with circular top views, and are separately arranged along the linear dummy bumps 130d2 and the segmental dummy bumps 130d3. Also, as compared to the linear dummy bumps 130d2 and the segmental dummy bumps 130d3, the functional bumps 130f may be formed as pillar structures and may have circular top view shapes.

In the semiconductor package 50c shown in FIG. 5C, dummy bumps 130d4 of the package seal ring PSR may be formed as pillar structures with circular top view shapes, as similar to or identical with the functional bumps 130f. According to some embodiments, the dummy conductive pads 112d, 128d at bottom and top sides of the dummy bumps 130d4 are formed as circular patterns, segmental patterns line patterns or combinations thereof, and are connected to the dummy bumps 130d4. In addition, as similar to the dummy bumps 130d4 and the functional bumps 130f, the dummy through substrate vias 114d may be formed as pillar structures with circular top views, and are separately arranged along the dummy bumps 130d4.

Referring to FIG. 5D, the package seal ring PSR in the semiconductor package 50d includes dummy bumps 130d5 arranged along the edges of the device die 100a, and includes dummy bumps 130d6 laterally surrounded by the segmental dummy bumps 130d5. That is, the dummy bumps 130d5 are separately arranged along an outer annulus path close to the edges of the device die 100a, whereas the dummy bumps 130d6 are separately arranged along an inner annulus path surrounded by the outer annulus path. Further, some of the outer dummy bumps 130d5 each extending along a single edge of the device die 100a are formed as wall structures, which are shown as line segments in plan view. Further, others of the outer dummy bumps 130d5 may respectively extend along intersected edges of the device die 100a, and are each shown as a pattern with “L” shape in plan view. Similarly, some of the inner dummy bumps 130d6 each extending along a single edge of the device die 100a are formed as wall structures, which are shown as line segments in plan view. Optionally, others of the inner dummy bumps 130d6 may respectively extend along intersected edges of the device die 100a, and are each shown as a pattern with “L” shape in plan view.

Although not shown, the dummy conductive pads 112d, 128d of the package seal ring PSR at bottom and top sides of the dummy bumps 130d5, 130d6 may be formed in accordance with the dummy bumps 130d5, 130d6. Specifically, the dummy conductive pads 112d lying under the dummy bumps 130d5, 130d6 may be separately arranged along outer and inner annulus paths, and the dummy conductive pads 128d above the dummy bumps 130d5, 130d6 may be separately arranged along outer and inner annulus paths as well. Further, the segmental dummy bumps 130d5, 130d6 may be respectively in contact with segmental ones of the dummy conductive patterns 112d, 128d by bottom and top sides, while the dummy bumps 130d5, 130d6 with “L” shape top views may be respectively in contact with the dummy conductive patterns 112d, 128d with “L” shape top views by bottom and top sides.

On the other hand, the dummy through substrate vias 114d of the package seal ring PSR may not be formed in accordance with the dummy bumps 130d5, 130d6. Specifically, the dummy through substrate vias 114d may be formed as pillar structures with circular top views, and are separately arranged along the outer dummy bumps 130d5 and the inner dummy bumps 130d6. Also, the functional bumps 130f may be formed as pillar structures with circular top views as well.

Referring to FIG. 5E, the package seal ring PSR in the semiconductor package 50e may include three layers of the dummy bumps. Specifically, outer dummy bumps 130d7 may be separately arranged along an outer annulus path close to the edges of the device die 100a; first inner dummy bumps 130d8 may be separately arranged along a first inner annulus path surrounded by the outer annulus path; and second inner dummy bumps 130d9 may be separately arranged along a second inner annulus path surrounded by the first inner annulus path. As similar to the dummy bumps 130d5, 130d6 described with reference to FIG. 5D, the outer dummy bumps 130d7 may include segmental ones and ones with “L” shape top views. Similarly, the first inner dummy bumps 130d8 may include segmental ones, and may optionally include ones with “L” shape top views. Also, the second inner dummy bumps 130d9 may include segmental ones, and may optionally include ones with “L” shape top views.

Although not shown, the dummy conductive pads 112d, 128d of the package seal ring PSR at bottom and top sides of the dummy bumps 130d7, 130d8, 130d9 may be formed in accordance with the dummy bumps 130d7, 130d8, 130d9. Specifically, the dummy conductive pads 112d lying under the dummy bumps 130d7, 130d8, 130d9 may be separately arranged along the outer annulus path, the first inner annulus path and the second inner annulus path. Similarly, the dummy conductive pads 128d above the dummy bumps 130d7, 130d8, 130d9 may be separately arranged along the outer annulus path, the first inner annulus path and the second inner annulus path as well. Further, the segmental dummy bumps 130d7, 130d8, 130d9 may be respectively in contact with segmental ones of the dummy conductive patterns 112d, 128d by bottom and top sides, while the dummy bumps 130d7, 130d8, 130d9 with “L” shape top views may be respectively in contact with the dummy conductive patterns 112d, 128d with “L” shape top views by bottom and top sides.

On the other hand, the dummy through substrate vias 114d of the package seal ring PSR may not be formed in accordance with the dummy bumps 130d7, 130d8, 130d9. Specifically, the dummy through substrate vias 114d may be formed as pillar structures with circular top views, and are separately arranged along the outer dummy bumps 130d7, the first inner dummy bumps 130d8 and the second inner dummy bumps 130d9. Also, the functional bumps 130f may be formed as pillar structures with circular top views as well.

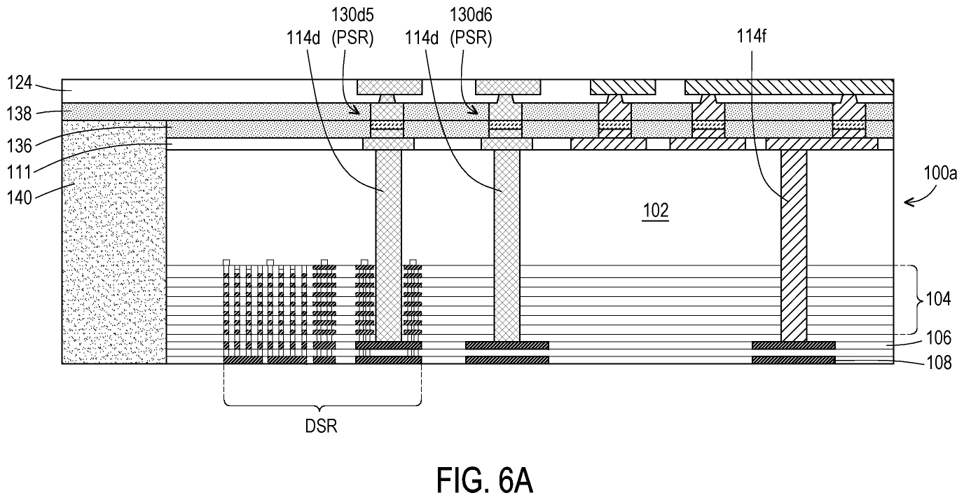

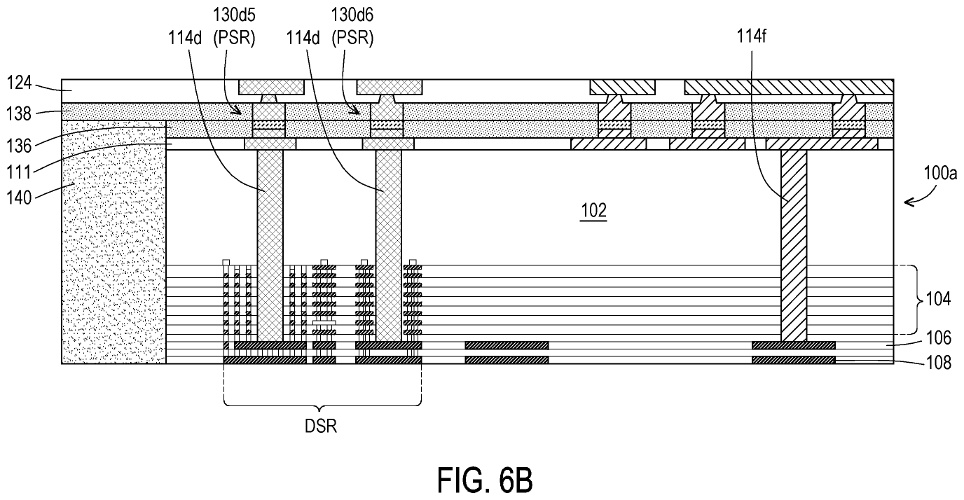

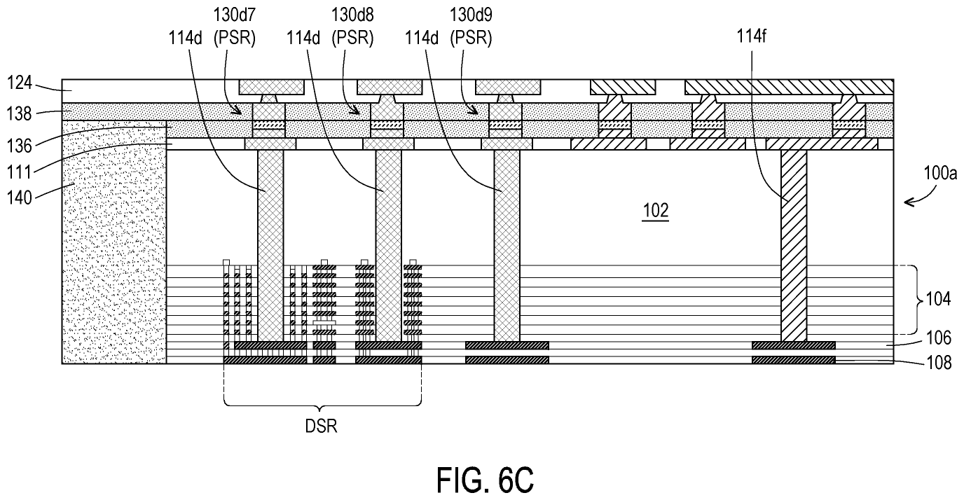

FIG. 6A is an enlarged schematic cross-sectional view showing a portion of the package seal ring PSR in the semiconductor package 50d shown in FIG. 5D, according to some embodiments of the present disclosure.

Referring to FIG. 6A, in some embodiments, the die seal ring DSR of the device die 100a may extend in between the inner dummy bumps 130d6 and the edges of the device die 100a, while being overlapped with the outer dummy bumps 130d5. In these embodiments, the dummy through substrate vias 114d right below the inner dummy bumps 130d6 may be disposed at an inner side of the die seal ring DSR that is distant from the edges of the device die 100a, and may be laterally spaced apart from the die seal ring DSR. On the other hand, the dummy through substrate vias 114d right below the outer dummy bumps 130d5 may be inserted into the die seal ring DSR, and may be respectively surrounded by the die seal ring DSR.

FIG. 6B is an enlarged schematic cross-sectional view showing a portion of the package seal ring PSR in the semiconductor package 50d shown in FIG. 5D, according to some other embodiments of the present disclosure.

Referring to FIG. 6B, in some other embodiments, the die seal ring DSR of the device die 100a is overlapped with the outer dummy bumps 130d5 and the inner dummy bumps 130d6. In these embodiments, the dummy through substrate vias 114d right below the outer dummy bumps 130d5 and the dummy through substrate vias 114d right below the inner dummy bumps 130d5 may be both inserted into the die seal ring DSR, and are respectively surrounded by the die seal ring DSR.

FIG. 6C is an enlarged schematic cross-sectional view showing a portion of the package seal ring PSR in the semiconductor package 50e shown in FIG. 5E, according to some other embodiments of the present disclosure.

Referring to FIG. 6C, according to some embodiments, the die seal ring DSR of the device die 100a may extend in between the second inner dummy bumps 130d9 and the edges of the device die 100a, while being overlapped with the first inner dummy bumps 130d8 and the outer dummy bumps 130d7. In these embodiments, the dummy through substrate vias 114d right below the second inner dummy bumps 130d9 may be disposed at an inner side of the die seal ring DSR that is distant from the edges of the device die 100a, and may be laterally spaced apart from the die seal ring DSR. On the other hand, the dummy through substrate vias 114d right below the first inner dummy bumps 130d8 and the dummy through substrate vias 114d right below the outer dummy bumps 130d7 may be both inserted into the die seal ring DSR, and may be respectively surrounded by the die seal ring DSR.

As described, many variations can be applied to the package seal ring PSR. In further embodiments, variations related to die arrangement and die stacking manner can be applied.

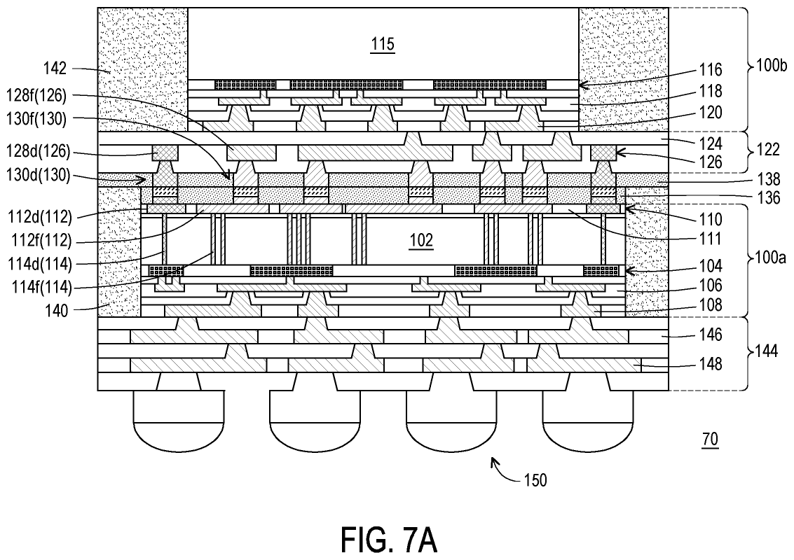

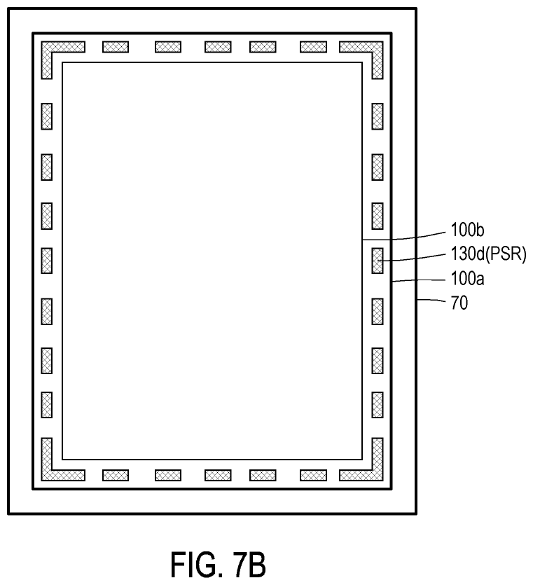

FIG. 7A is a schematic cross-sectional view illustrating a semiconductor package 70, according to some embodiments of the present disclosure.

The semiconductor package 70 is similar to the semiconductor package 10 as described with reference to FIG. 1A through FIG. 1C, except for a few differences. Specifically, in the semiconductor package 70 shown in FIG. 7A, the device die 100b is placed in line with the device die 100a, rather than being laterally offset from the device die 100a. As a result, the device die 100b may entirely overlap the device die 100a. As the device die 100b may not have a portion lying outside the range of the device die 100a, connection between the device die 100b and the redistribution structure 144 without passing through the device die 100a may not be available, thus through encapsulant vias for establishing such connection may be omitted. Further, since the device die 100b is placed in line with the device die 100a, there may not be required to place a dummy die aside the device die 100b for balancing non-uniformity of thermal expansion coefficient across the encapsulant 142.

A manufacturing process for forming the semiconductor package 70 is similar to the process described with reference to FIG. 2A through FIG. 2C and FIG. 3A through FIG. 3H, except that placement of the dummy die 154 may be omitted, formation of the through encapsulant vias 152 may be skipped, and placement of the device die 100b has to be adjusted. For purpose of conciseness, the entire process may not be repeated again.

FIG. 7B is a schematic plan view of the semiconductor package 70, according to some embodiments of the present disclosure. It should be noted that, for illustration purpose, only a few elements in the semiconductor package 70 are shown in FIG. 7B.

As shown in FIG. 7B, the device die 100b may entirely overlap the device die 100a. According to some embodiments, the device die 100b is smaller in size as compared to the device die 100a. In these embodiments, the package seal ring PSR (only the dummy bumps 130d of the package seal ring PSR are shown) disposed along the edges of the device die 100a may be positioned outside the range of the device die 100b. That is, the package seal ring PSR may extend in between the edges of the device die 100a and the edges of the device die 100b, and the device die 100b may be laterally surrounded by the package seal ring PSR.

Further, as the device die 100b may entirely overlap the device die 100a, the functional conductive pads 128f, the functional bumps 130f and the functional conductive pads 112f within the range of the device die 100b can all be used for establishing communication between the device dies 100a, 100b. In addition, since through encapsulant vias may be absent, there may not be the through encapsulant via region 158 described with reference to FIG. 1B.

It should be noted that, various designs of the package seal ring PSR as described with reference to FIG. 1B and FIG. 5A through FIG. 5E can be applied to the semiconductor package 70. In addition, several configurations of the package seal ring PSR and the die seal ring DSR described with reference to FIG. 1C and FIG. 6A through FIG. 6C can be applied to the semiconductor package 70 as well. Further, although the bumps 130 in the semiconductor package 70 are depicted as being laterally confined by the bonding layers 136, 138, the bumps 130 can be alternatively sealed by the underfill 400 described with reference to FIG. 4, and manufacturing process for forming the semiconductor package 70 may be modified accordingly.

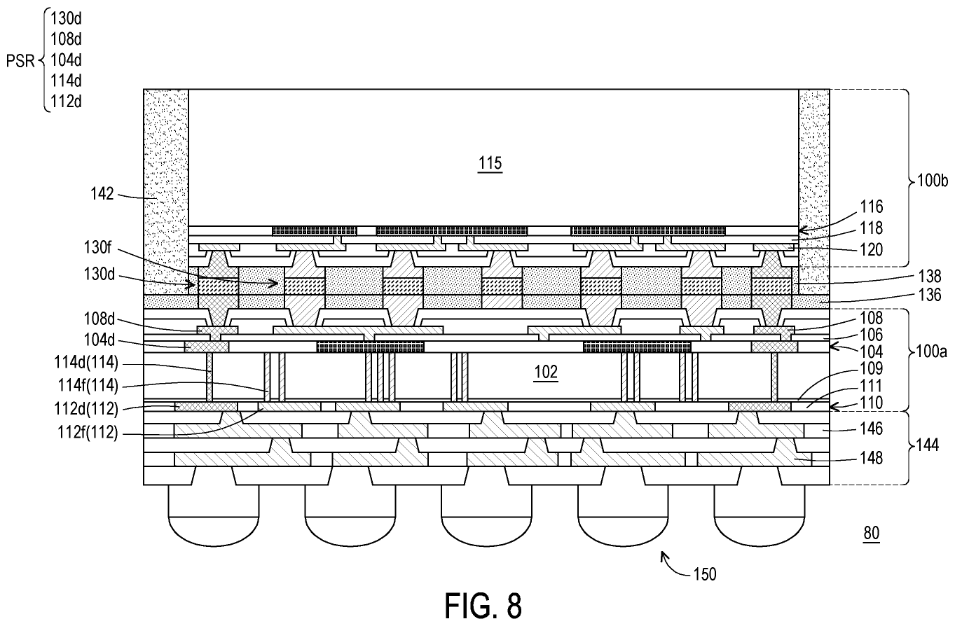

FIG. 8 is a schematic cross-sectional view illustrating a semiconductor package 80, according to some embodiments of the present disclosure.

The semiconductor package 80 is similar to the semiconductor package 70 described with reference to FIG. 7A and FIG. 7B. A major difference between the semiconductor packages 70, 80 lies in that the device dies 100a, 100b in the semiconductor package 70 are arranged according to the face-to-back die stacking configuration, while the device dies 100a, 100b in the semiconductor package 80 are arranged according to a face-to-face die stacking configuration.

Specifically, as shown in FIG. 8, the metallization layers 104, the dielectric layers 106 and the routing elements 108 formed at the active side of the device die 100a face toward the metallization layers 116, the dielectric layers 118 and the routing elements 108 formed at the active side of the device die 100b. According to some embodiments, the redistribution structure 122 described with reference to FIG. 1A, FIG. 4 and FIG. 7 is absent in the semiconductor package 80, and the bumps 130 in between the device dies 100a, 100b connect the active side of the device die 100a to the active side of the device die 100b. In addition, the bonding layer 136 may extend along the active side of the device die 100a, whereas the bonding layer 138 may extend along the active side of the device die 100b. On the other hand, the back side redistribution structure 110 at the back side of the device die 100a may be in contact with the redistribution structure 144.

Based on such face-to-face die stacking manner, the dummy bumps 130d may be connected to the dummy through substrate vias 114f of the device die 100a via some of the routing elements 108 and some of the conductive features in the metallization layers 104 at the active side of the device die 100a. These routing elements 108 in connection with the dummy bumps 130d may be referred to as dummy routing elements 108d. Similarly, the conductive features in the metallization layers 104 and in connection with the dummy bumps 130d may be referred to as dummy conductive features 104d. That is, the package seal ring PSR in the semiconductor package 80 may not only include the dummy bumps 130d, the dummy through substrate vias 114d and the dummy conductive pads 112d, but also include the dummy routing elements 108d and the dummy conductive features 104d. Further, as the redistribution structure 122 described with reference to FIG. 1A, FIG. 4 and FIG. 7 may be absent in the semiconductor package 80, the package seal ring PSR in the semiconductor package 80 may not include the dummy conductive pads 128d in the redistribution structure 122.

In some embodiments, while the device die 100b and the bonding layer 138 extending along the active side of the device die 100b are laterally encapsulated by the encapsulant 142, the device die 100a and the bonding layer 136 may not be encapsulated. In these embodiments, singulation of the semiconductor package 80 may be performed by cutting through the encapsulant 142, the bonding layer 136, the device die 100a and the redistribution structure 144. In this way, the device die 100a, the bonding layer 136 and the redistribution structure 144 may extend to sidewalls of the semiconductor package 80, and sidewalls of the encapsulant 142, the bonding layer 136, the device die 100a and the redistribution structure 144 may be substantially coplanar. Further, sidewalls of the device die 100b and the bonding layer 138 may be laterally recessed from the sidewalls of the bonding layer 136, the device die 100a and the redistribution structure 144. To establish contact with the active side of the device die 100b, the dummy bumps 130d of the package seal ring PSR may be formed at an inner side of the edges of the device die 100b. On the other hand, rest part of the package seal ring PSR may be located within the range of the device die 100b or span across the edges of the device die 100b, while being within the range of the device die 100a.

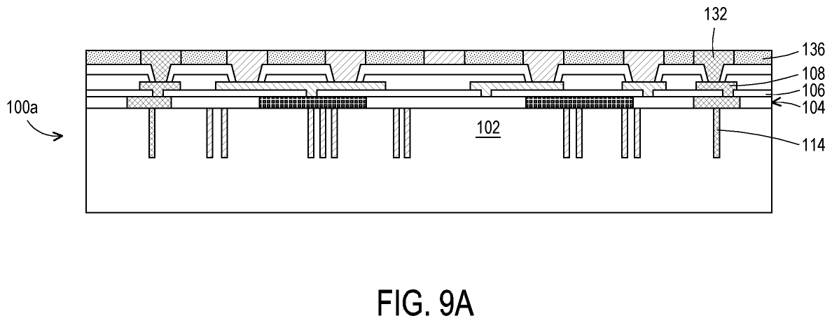

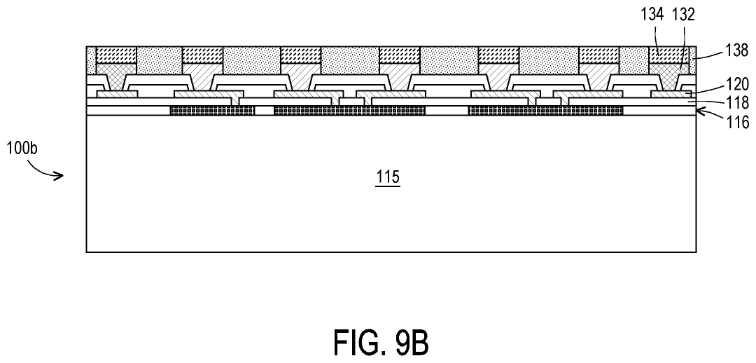

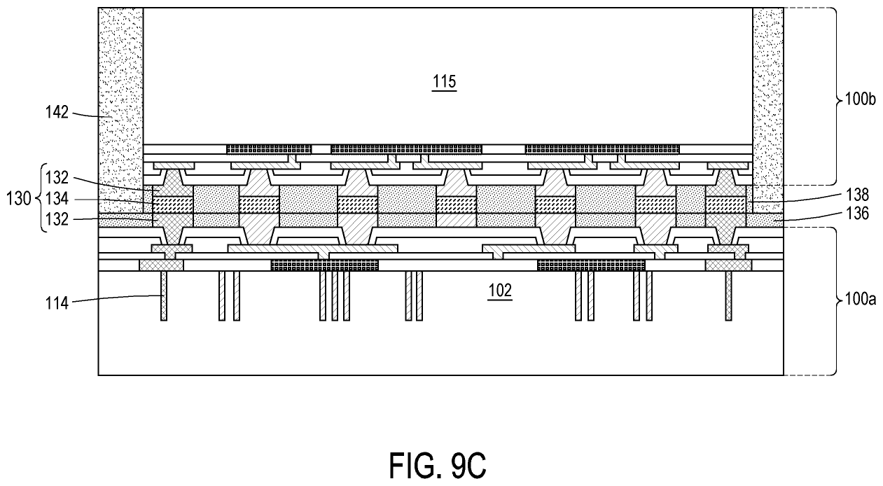

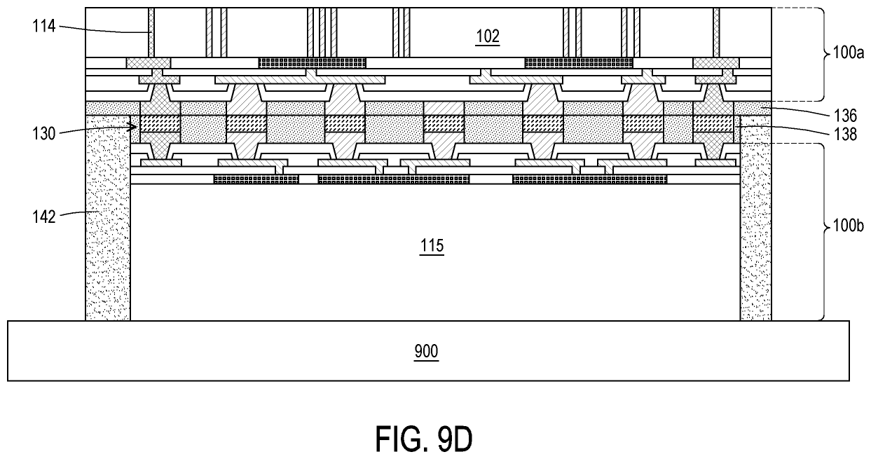

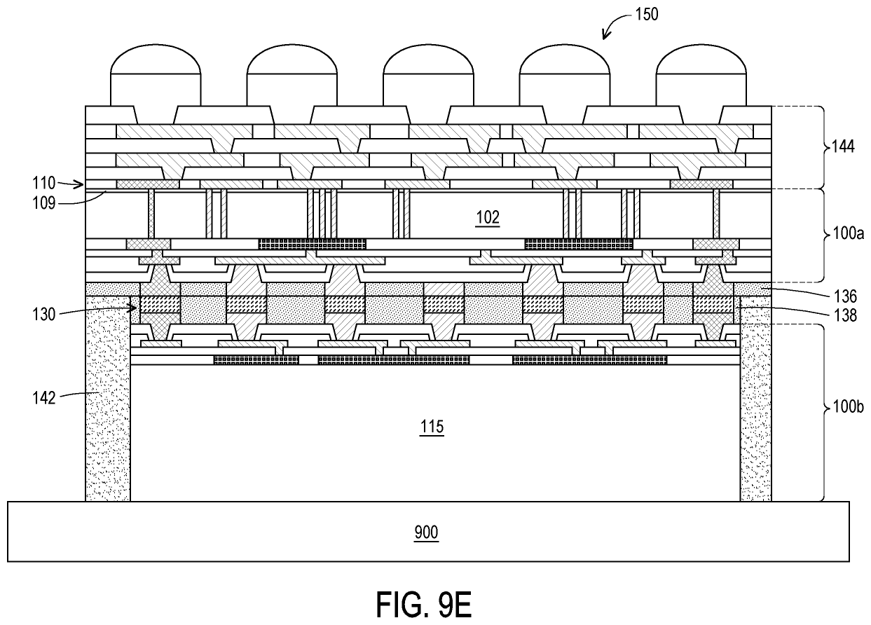

FIG. 9A through FIG. 9D are schematic cross-sectional views illustrating a process for forming the semiconductor package 80, according to some embodiments of the present disclosure.

Referring to FIG. 9A, after front side processing, the device die 100a in wafer form is subjected to a process similar to the process described with reference to FIG. 2A and FIG. 2B, for forming the lower conductive posts 132 of the bumps 130 and the bonding layer 136 on the active side of the device die 100a. Currently, the semiconductor substrate 102 of the device die 100a has not been thinned from back side, or has not been thinned to an eventual thickness. Thereby, the through substrate vias 114 are not exposed at the back side of the semiconductor substrate 102, but are embedded in the semiconductor substrate 102. Further, the liner layer 109 and the back side redistribution structure 110 have not been formed.

Referring to FIG. 9B, as similar to the device die 100a, the device die 100b in wafer form is subjected to front side processing, and the upper conductive posts 132 and the solder layers 134 of the bumps 130 as well as the bonding layer 138 are formed on the active side of the device die 100b. Thereafter, the device die 100b along with the bonding layer 138 may be singulated.

Subsequently, in a process similar to the process described with reference to FIG. 2C, the structure as shown in FIG. 9B is flipped over and attached onto the structure shown in FIG. 9A. As a result shown in FIG. 9C, the bonding layers 136, 138 are bonded with each other, and the bumps 130 are assembled while being enclosed by the bonding layers 136, 138. As further shown in FIG. 9C, after the bonding process, the device die 100b and the bonding layer 138 may be encapsulated by the encapsulant 142.

Referring to FIG. 9D, then the current package structure may be flipped over and attached onto a carrier substrate 900. As the back side of the semiconductor substrate 102 is exposed, a grinding process may be performed to thin the semiconductor substrate 102, till the through substrate vias 114 are exposed.

Referring to FIG. 9E, subsequently, the liner layer 109 and the back side redistribution structure 110 are formed on the back side of the device die 100b. Further, the redistribution structure 144 may be formed on the back side redistribution structure 110 of the device die 100b. Also, the package I/Os 150 may be deployed on the redistribution structure 144.

Thereafter, the current package structure may be detached from the carrier substrate 900, and subjected to singulation while being mounted on a dicing frame (not shown), for forming the semiconductor package 80. Optionally, the semiconductor substrate 115 of the device die 100b and the encapsulant 142 may be further thinned before the singulation.

It should be noted that, various designs of the package seal ring PSR as described with reference to FIG. 1B and FIG. 5A through FIG. 5E can be applied to the semiconductor package 80. In addition, several configurations of the package seal ring PSR and the die seal ring DSR described with reference to FIG. 1C and FIG. 6A through FIG. 6C can be applied to the semiconductor package 80 as well. Further, although the bumps 130 in the semiconductor package 80 are depicted as being laterally confined by the bonding layers 136, 138, the bumps 130 can be alternatively sealed by the underfill 400 described with reference to FIG. 4, and manufacturing process for forming the semiconductor package 70 may be modified accordingly.

As above, a three-dimensional semiconductor package and a manufacturing method thereof are provided. Device dies are stacked in the three-dimensional semiconductor package, and are communicated with each other via bumps provided between the device dies. In order to prevent these functional bumps from damages caused by stress and invasion of moisture and/or chemicals, a package seal ring is disposed around the functional bumps. Specifically, the package seal ring includes dummy bumps that are structurally identical with the functional bumps but may not participate in signal transmission. The dummy bumps may be separately arranged along edges of the bottom device die, or merged into an annulus structure. Either way, the dummy bumps laterally surround the functional bumps, and protect the functional bumps from the stress, moisture and/or chemical induced damages. According to some embodiments, the package seal ring further includes dummy through substrate vias formed in the bottom device die. The dummy through substrate vias are connected to the dummy bumps, and laterally surround functional through substrate vias in the bottom device die that contribute to signal transmission. In this way, the functional through substrate vias can be protected by the package seal ring as well. Also, in the embodiments that the dummy bumps are disposed between vertically separated redistribution structures, the package seal ring may further include dummy conductive pads of the redistribution structures that are in contact with the dummy bumps. In these embodiments, the dummy conductive pads can shield surrounded conductive pads from possible damages. Therefore, according to various embodiments, the semiconductor package may be resulted with improved reliability by further incorporating the package seal ring.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In an aspect of the present disclosure, a semiconductor package is provided. The semiconductor package comprises: a first device die and a second device die stacked over the first device die; functional bumps, disposed between the first device die and the second device die, and electrically connected to the first device die and the second device die; and a first seal ring, comprising at least one dummy bump arranged along edges of the first device die and disposed between the first and second device dies, and laterally surrounding the functional bumps.

In another aspect of the present disclosure, a semiconductor package is provided. The semiconductor package comprises: a first device die and a second device die overlapping the first device die; functional bumps, disposed between the first device die and the second device die, and electrically connected to the first device die and the second device die; a first seal ring, comprising at least one dummy bump laterally surrounding the functional bumps between the first and second device dies; a first bonding layer, disposed between the first device die and the second device die, and extending along a side of the first device die facing toward the second device die; and a second bonding layer, disposed between the first bonding layer and the second device die and bonded to the first bonding layer, wherein the functional bumps and the at least one dummy bump extend through the first and second bonding layers.

In yet another aspect of the present disclosure, a method for manufacturing a semiconductor package is provided. The method comprises: forming functional bumps to establish vertical signal transmission paths between a first device die and a second device die stacked over the first device die; and forming a first seal ring along edges of the first device die, comprising forming at least one dummy bump in between the first and second device dies and laterally surrounding the functional bumps.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package, comprising:
a first device die and a second device die stacked over the first device die;
functional bumps, disposed between the first device die and the second device die, and electrically connected to the first device die and the second device die; and
a first seal ring, comprising at least one dummy bump arranged along edges of the first device die and disposed between the first and second device dies, and laterally surrounding the functional bumps.

2. The semiconductor package according to claim 1, wherein the at least one dummy bump is structurally identical with the functional bumps.

3. The semiconductor package according to claim 1, wherein the at least one dummy bump comprises multiple dummy bumps separately arranged along the edges of the first device die.

4. The semiconductor package according to claim 1, wherein the at least one dummy bump comprises first and second segmental dummy bumps separately arranged along the edges of the first device die, each of the first segmental dummy bumps extends along a single one of the edges of the first device die, and each of the second segmental dummy bumps extends along intersected ones of the edges of the first device die.

5. The semiconductor package according to claim 1, wherein the at least one dummy bump comprises segmental and linear dummy bumps, the segmental dummy bumps are separately arranged along each of first and second ones of the edges of the first device die, and the linear dummy bumps continuously extend along third and fourth ones of the edges of the first device die, respectively.

6. The semiconductor package according to claim 1, wherein the at least one dummy bump comprises an annulus dummy bump continuously extending along the edges of the first device die.

7. The semiconductor package according to claim 1, wherein the at least one dummy bump comprises outer dummy bumps and inner dummy bumps, the outer dummy bumps are separately arranged along an outer annulus path close to the edges of the first device die, and the inner dummy bumps are separately arranged along an inner annulus path laterally surrounded by the outer annulus path.

8. The semiconductor package according to claim 1, wherein the at least one dummy bump comprises outer dummy bump, first inner dummy bumps and second inner bumps, the outer dummy bumps are separately arranged along an outer annulus path close to the edges of the first device die, the first inner dummy bumps are separately arranged along a first inner annulus path laterally surrounded by the outer annulus path, and the second inner dummy bumps are separately arranged along a second inner annulus path laterally surrounded by the first inner annulus path.

9. The semiconductor package according to claim 1, wherein the first seal ring further comprises dummy through substrate vias formed into the first device die and in contact with the at least one dummy bump.

10. The semiconductor package according to claim 9, wherein the dummy through substrate vias are laterally surrounded by a second seal ring in the first device die.

11. The semiconductor package according to claim 9, wherein a first group of the dummy through substrate vias are inserted into a second seal ring of the first device die, and a second group of the dummy through substrate vias are laterally surrounded by the second seal ring.

12. A semiconductor package, comprising:
a first device die and a second device die overlapping the first device die;
functional bumps, disposed between the first device die and the second device die, and electrically connected to the first device die and the second device die;
a first seal ring, comprising at least one dummy bump laterally surrounding the functional bumps between the first and second device dies;
a first bonding layer, disposed between the first device die and the second device die, and extending along a side of the first device die facing toward the second device die; and
a second bonding layer, disposed between the first bonding layer and the second device die and bonded to the first bonding layer, wherein the functional bumps and the at least one dummy bump extend through the first and second bonding layers.

13. The semiconductor package according to claim 12, wherein sidewalls of the first bonding layer are substantially coplanar with sidewalls of the first device die.

14. The semiconductor package according to claim 12, further comprising a redistribution structure lying in between the second bonding layer and the second device die, wherein the second bonding layer lines along the redistribution structure, and has sidewalls substantially coplanar with sidewalls of the redistribution structure.

15. The semiconductor package according to claim 14, wherein the first seal ring further comprises dummy conductive pads formed in the redistribution structure and in contact with the dummy bumps.

16. The semiconductor package according to claim 12, wherein the second bonding layer extends along a side of the second device die facing toward the first device die, and has sidewalls substantially coplanar with sidewalls of the second device die.

17. A method for manufacturing a semiconductor package, comprising:
forming functional bumps to establish vertical signal transmission paths between a first device die and a second device die stacked over the first device die; and
forming a first seal ring along edges of the first device die, comprising forming at least one dummy bump in between the first and second device dies and laterally surrounding the functional bumps.

18. The method for manufacturing the semiconductor package according to claim 17, wherein forming the first seal ring further comprises forming dummy through substrate vias into the first device die, and the at least one dummy bump overlaps and connects to the dummy through substrate vias.

19. The method for manufacturing the semiconductor package according to claim 17, wherein forming the first seal ring further comprises forming dummy conductive pads in a redistribution structure lying between the second bonding layer and the second device die, and the dummy conductive pads overlap and are connect to the dummy bumps.

20. The method for manufacturing the semiconductor package according to claim 17, further comprising:
forming first and second bonding layers during formation of the functional bumps and the at least one dummy bump, wherein the first and second bonding layers are bonded with each other, and laterally surround the functional bumps and the at least one dummy bump.
